(19) United States
(12) Patent Application Publication
(10) Pub. No.: US 2005/0092243 A1
(43) Pub. Date: May 5, 2005

(54) Processing apparatus and method

(75) Inventor: Nobumasa Suzuki, Ibaraki (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, TOKYO (JP)

(21) Appl. No.: 10/766,816

(22) Filed: Jan. 30, 2004

(30) Foreign Application Priority Data
Nov. 4, 2003 (JP) 2003-374824

(51) Int. Cl. C23C 16/00; H01L 21/31; H01L 21/469

(52) U.S. Cl. 118/715; 118/722

(57) ABSTRACT

A processing apparatus that provides a plasma treatment to an object includes a process chamber that accommodates an object to be processed, and generates plasma, a gas introducing part for introducing gas into the process chamber, and a mechanism that arranges the object at an upper side in a flow of the gas than an plasma generating region.

This application claims a benefit of priority based on Japanese Patent Application No. 2003-374824, filed on Nov. 4, 2003, which is hereby incorporated by reference herein in its entirety as if fully set forth herein.

### BACKGROUND OF THE INVENTION

The present invention relates generally to a processing apparatus and method, and more particularly to control over reactions between process-gas generated active species for plasma processing and an object to be processed. The present invention is suitable, for example, for plasma processing that controllably forms an extremely thin film of several molecular layers.

A CVD apparatus, an etcher, an asher, a surface modification apparatus, etc. have been known as microwave plasma processing apparatuses that uses microwaves for a plasma generating excitation source. In processing an object, this microwave plasma processing apparatus typically introduces process gas in a process chamber, and supplies the microwaves from an external microwave supply unit into the process chamber through a dielectric window to generate plasma in the process chamber for excitations, dissociations, and reactions of the gas, and a surface treatment to the object in the process chamber. Japanese Patent Application Publication No. 3-1531, for example, has proposed a film formation process with a microwave processing apparatus.

However, when the microwave plasma processing apparatus forms an extremely thin film with, for example, a thickness of 2 nm or smaller through a film formation or surface treatment, for example, in order to form a gate oxide film on a silicon substrate, the process time becomes so short as 1 second or shorter in comparison with the stable controllable time, e.g., 5 seconds that the controllability over the thickness deteriorates.

### BRIEF SUMMARY OF THE INVENTION

Accordingly, it is an exemplary object of the present invention to provide a plasma processing apparatus and method that eliminates the prior art disadvantages, and improves the thickness controllability in forming an extremely thin film.

A processing apparatus of one aspect according to the present invention that provides a plasma treatment to an object includes a process chamber that accommodates an object to be processed, and generates plasma, a gas introducing part for introducing gas into the process chamber. The apparatus further includes a mechanism that arranges the object at an upper side in a flow of the gas than an plasma generating region, an exhaust mechanism arranged closer to a plasma generating region than the object, or a mechanism for maintaining a concentration of active species from 10⁹ to 10¹¹ cm⁻³.

The processing apparatus may further include, between the object and the plasma generating region, a conductance adjuster for maintaining, within a predetermined range, a concentration of active species in a process space that encloses the object. In this case, the conductance adjuster serves as the above maintenance mechanism. The conductance adjuster may be a plate bored with plural holes.

The processing apparatus may arrange the exhaust mechanism at a side of the plasma generating region in that is partitioned by the conductance adjuster, and the gas introducing part at a side of the object in the process chamber that is partitioned by the conductance adjuster. The gas introducing part may include a first gas inlet for introducing into the process chamber process gas for the plasma treatment to the object, and a second gas inlet for introducing inert gas into the process chamber, and wherein the exhaust mechanism and the first gas inlet are arranged at a side of the plasma generating region in the process chamber that is partitioned by the conductance adjuster, and wherein the second gas inlet is located at a side of the object side in the process chamber that is partitioned divided by the conductance adjuster.

The plasma treatment may be oxidation or nitridation to a surface of the object.

A processing method of another aspect according to the present invention that accommodates an object in a process chamber and introduces gas containing oxygen into the process chamber to provide a plasma treatment to the object so as to form an oxide film having a thickness of 8 nm or smaller includes the steps of maintaining a concentration of active species on the object from 10⁹ to 10¹¹, and conducting the plasma treatment for a process time longer than 5 seconds.

Other objects and further features of the present invention will become readily apparent from the following description of the preferred embodiments with reference to accompanying drawings.

### BRIEF DESCRIPTION OF THE DRAWINGS

FIG. 1 is a schematic sectional view of a microwave plasma processing apparatus of one embodiment according to the present invention.

FIG. 2 is a schematic sectional view of a microwave plasma processing apparatus of first, fourth and fifth embodiments according to the present invention.

FIG. 3 is a schematic sectional view of a microwave plasma processing apparatus of a second embodiment according to the present invention.

FIG. 4 is a schematic sectional view of a microwave plasma processing apparatus of a third embodiment according to the present invention.

### DETAILED DESCRIPTION OF THE PREFERRED EMBODIMENTS

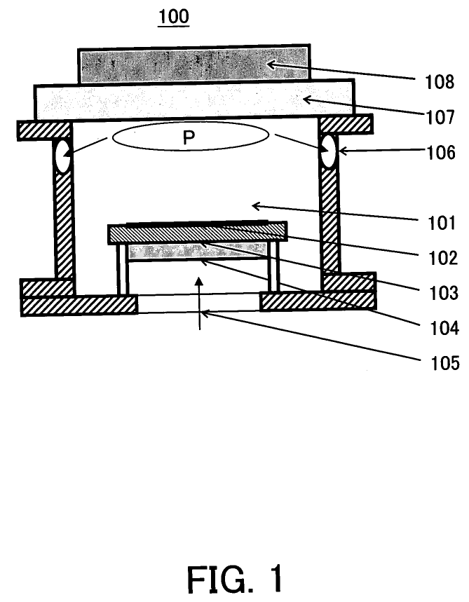

A detailed description will now be given of a microwave plasma processing apparatus (simply referred to as a “processing apparatus” hereinafter) 100 of one embodiment according to the present invention with reference to accompanying drawings. Here, FIG. 1 is a schematic sectional view of the processing apparatus 100. As illustrated, the processing apparatus 100 is connected to a microwave oscillator or source, includes a plasma process chamber 101, a substrate to be processed 102, a susceptor (or a support table) 103, a temperature control part 104, a gas introducing part 105, an exhaust channel 106, a dielectric window 107, and a microwave supply unit 108, and applies a plasma treatment to the substrate 102.

The microwave oscillator is, for example, a magnetron and generates microwaves, for example, of 2.45 GHz. Nevertheless, the present invention can elect any appropriate microwave frequency between 0.8 Hz and 20 GHz. The microwaves are then converted by a mode converter into a TM, TE or TEM mode or the like, before propagating through a waveguide. The microwave waveguide channel is equipped with an isolator, an impedance matching unit, and the like. The isolator prevents reflected microwaves from returning to the microwave oscillator, and absorbs the reflected waves. The impedance matching unit, which is made of a 4E tuner, an EH tuner, a stab tuner, etc., includes a power meter that detects the strength and phase of each of a progressive wave supplied from the microwave oscillator to the load and a reflected wave that is reflected by the load and returning to the microwave oscillator, and serves to match between microwave oscillator and a load side.

The plasma process chamber 101 is a vacuum container that accommodates the substrate 102 and provides a plasma treatment to the substrate 102 under a reduced pressure or vacuum environment. FIG. 1 omits a gate valve that receives the substrate 102 from and feeds the substrate 102 to a load lock chamber (not shown), and the like.

The substrate 102 may be a semiconductor, a conductor or an insulator. The conductive substrate can be made of metals, such as Fe, Ni, Cr, Al, Mo, Au, Nb, Ta, V, Ti, Pt and Pb, or their alloy, such as brass and stainless steel. The insulated substrate can be SiO₂ systems, such as quarts and various glasses, inorganic materials, such as Si₃N₄, NaCl, KCl, LiF, CaF₂, BaF₂, Al₂O₃, AlN and MgO, organic films and windows, such as polyethylene, polyester, polycarbonate, cellulose acetate, polypropylene, polyvinyl chloride, polyvinylidene chloride, polystyrene, polyamide and polyimide.

The substrate 102 is placed on the susceptor 103. If necessary, the susceptor 103 is made height-adjustable. The susceptor 103 is accommodated in the plasma process chamber 101, and supports the substrate 102.

The temperature control part 104 includes a heater, etc., which controls the temperature suitable for treatments, for example, between 200° C. and 400° C. The temperature control part 104 includes, for example, a thermometer that detects the temperature of the susceptor 103, and a controller that controls electrification from a power source (not shown) to a heater line.

The gas introducing part 105 is provided at the bottom of the plasma process chamber 101, and supplies gas for a plasma treatment into the plasma process chamber 101. The gas introducing part 105 is part of gas supply means that includes a gas source, a valve, a mass flow controller, and a gas pipe that connects them, and supplies process gas and discharge gas to be excited by the microwaves for predetermined plasma. It may add inert gas, such as Xe, Ar and He for prompt plasma ignitions at least at the ignition time. The inert gas ionizes easily, and improves plasma ignitions at the time of microwave introduction. As described later, the gas introducing part 105 is partitioned, for example, into an inlet that introduces process gas, and another inlet that introduces inert gas, and positions these inlets at different positions. For example, the process gas inlet is provided at the top and the inert gas inlet is provided at the bottom so as to form the inert gas flow from down to up so that the inert gas hinders the process-gas generated active species from reaching the substrate 102.

The gas introducing part 105 directs, as shown in FIG. 1, from the bottom to the top. As a result, the substrate 102 is located at an upper portion than a surface of the dielectric window 107 at a side of the process chamber 101, around which the plasma is generated, or a plasma generating region P. As a result, the gas is supplied to the surface of the substrate 102 via the plasma generating region P that occurs near the dielectric window 107, and the gas-generated, active-species concentration on the substrate remarkably reduces to 10⁹ to 10¹¹ cm⁻³, which is much lower than that in a configuration that arranges the gas introducing part near the element 106 in FIG. 1.

The CVD method can use known gas to form a thin film on a substrate.

A material used to form Si-system semiconductor thin films, such as a-Si, poly-Si and SiC, needs to be gas or easily turn to gas at the room temperature and the ordinary pressure, and includes an inorganic silane group, such as SiH₄ and Si₂H₆, an organic silane group, such as tetraethylsilane (TES), tetramethylsilane (TMS), dimethylsilane (DMS), dimethyldifluorosilane (DMDFS) and dimethyldichlorosilane (DMDCS), and a silane halide group, such as SiF₄, Si₂F₆, Si₃F₈, SiHF₃, SiH₂F₂, SiCl₄, Si₂Cl₆, SiHCl₃, SiH₂Cl₂, SiH₃Cl and SiCl₂F₂. Additional gas or carrier gas that can be mixed and introduced with Si material gas includes H₂, He, Ne, Ar, Kr, Xe and Rn.

A material used to form Si-compound thin films, such as Si₃N₄ and SiO₂, needs to be gas or easily turn to gas at the room temperature and the ordinary pressure, and includes an inorganic silane group, such as SiH₄ and Si₂H₆, an organic silane group, such as tetraethoxysilane (TEOS), tetramethoxysilane (TMOS), octamethylcyclotetrasilane (OMCTS), dimethyldifluorosilane (DMDFS), dimethyldichlorosilane (DMDCS), and a silane halide group, such as SiF₄, Si₂F₆, Si₃F₈, SiHF₃, SiH₂F₂, SiCl₄, Si₂Cl₆, SiHCl₃, SiH₂Cl₂, SiH₃Cl and SiCl₂F₂. Simultaneously introduced nitrogen material gas or oxygen material gas includes N₂, NH₃, N₂H₄, hexamethyldisilazane (HMDS), O₂, O₃, H₂O, NO, N₂O, NO₂, etc.

A material used to form metal thin films, such as Al, W, Mo, Ti and Ta, includes organic metals, such as trimethylaluminum (TMAl), triethylaluminum (TEAl), triisobutylaluminum (TIBAl), dimethylaluminum hydride (DNAlH), tungsten carbonyl compounds (W(CO)₆), molybdenum carbonyl compounds (Mo(CO)₆), trimethylgallium (TMGa) and triethylgallium (TEGa), and metal halides, such as AlCl₃, WF₆ TiCl₃ and TaCl₅, etc. Simultaneously introduced additional gas or carrier gas includes H₂, He, Ne, Ar, Kr, Xe and Rn.

A material used to form metal-compound thin films, such as Al₂O₃, AlN, Ta₂O₅, TiO₂, TiN and WO₃, includes organic metals, such as trimethylaluminum (TMAl), triethylaluminum (TEAl), triisobutylaluminum (TIBAl), dimethylaluminum hydride (DNAlH), tungsten carbonyl compounds (W(CO)₆), molybdenum carbonyl compounds (Mo(CO)₆), trimethylgallium (TMGa) and triethylgallium (TEGa), and metal halides, such as AlCl₃, WF₆ TiCl₃ and TaCl₅, etc. Simultaneously introduced nitrogen material gas or oxygen material gas includes O₂, O₃, H₂O, NO, N₂O, NO₂, N₂, NH₃, N₂H₄, hexamethyldisilazane (HMDS), etc.

Etching gas to etch the surface of the substrate 102 includes F₂, CF₄, CH₂F₂, C₂F₆, C₃F₈, C₄F₈, CF₂Cl₂, SF₆, NF₃, Cl₂₁ CCl₄, CH₂Cl₂, C₂Cl₆, etc. Ashing gas to ash organic materials, such as photoresist, on the substrate 102 includes O₂, O₃, H₂O, NO, N₂O, NO₂, H₂, etc.

A surface modification to the substrate 102 can use appropriate gas, for example, for oxidation and nitridation to the substrate or a surface layer made of Si, Al, Ti, Zn and Ta, or for doping with B, As and P. The inventive film formation is applicable to a cleaning method, for example, for cleaning oxides, organic materials and heavy metals.

Oxidizing gas to oxide the surface of the substrate 102 includes O₂, O₃, H₂O, NO, N₂O, NO₂, etc., and nitridation gas to nitride the surface of the substrate 102 includes N₂, NH₃, N₂H₄, hexamethyldisilazane (HMDS), etc.

Cleaning/ashing gas to clean or ash organic materials, such as photoresist, on the surface of the substrate 102, which is introduced from the process gas inlet 105, includes O₂, O₃, H₂O, NO, N₂O, NO₂, H₂, etc. Cleaning gas to clean inorganic materials on the surface, which is introduced from the process gas inlet 105, includes F₂, CF₄, CH₂F₂, C₂F₆, C₄F₈, CF₂Cl₂, SF₆, NF₃, etc.

Characteristically, the exhaust channel or pipe 106 is provided around the top of the plasma process chamber 101, and connected to the vacuum pump (not shown). In other words, the exhaust channel 106 is provided between the plasma generating region and the substrate 102, thereby exhausting generated active species and reducing the active-species concentration on the substrate 102. The exhaust channel 106 forms a pressure regulation mechanism with a pressure regulating valve, a pressure sensor, a vacuum pump, and a controller. The controller (not shown) drives the vacuum pump and adjusts the pressure in the plasma process chamber 101 by controlling the pressure regulating valve, such as a VAT Vakuumventile A.G. (“VAT”) manufactured gate valve that has a pressure regulating function and an MKS Instruments, Inc. (“MKS”) manufactured exhaust slot valve, so that the pressure sensor for detecting the pressure of the process chamber 101 detects a predetermined value. As a result, the exhaust channel 106 adjusts the internal pressure of the plasma process chamber 101 suitable for processing. The pressure is preferably set in a range between 13 mPa and 1330 Pa, more preferably between 665 mPa and 665 Pa. The vacuum pump includes, for example, a turbo molecular pump (TMP), and is connected to the plasma process chamber 101 via the pressure regulating valve, such as a conductance valve (not shown).

The dielectric window 107 transmits the microwaves supplied from the microwave oscillator to the plasma process chamber 101, and serves as a diaphragm for the plasma process chamber 101.

The slot-cum plane microwave supply unit 108 serves to introduce the microwaves into the plasma process chamber 101 via the dielectric window 107, and can use a slot-cum non-terminal circle waveguide and a coaxial introducing plane multi-slot antenna when it can supply plane microwaves. The plane microwave supply unit 108 used for the inventive microwave plasma processing apparatus 100 can use a conductor, preferably those which have high conductivity for reduced microwave transmission losses, such as Al, Cu and SUS plated with Ag/Cu.

When the slot-cum plane microwave supply unit 108 is, for example, a slot-cum non-terminal circle waveguide, it includes a cooling channel and a slot antenna. The slot antenna forms a surface standing wave through interference of surface waves on the surface of the dielectric window 107 at its vacuum side. The slot antenna is a metal disc having, for example, radial slots, circumferential slots, multiple concentric or spiral T-shaped slots, and four pairs of V-shaped slots. An uniform treatment over the entire surface of the substrate 102 needs a supply of active species with good in-plane uniformity. The slot antenna arranges at least one slot, generates the plasma over a large area, and facilitates control over the plasma strength and uniformity.

A description will now be given of an operation of the processing apparatus 100. First, a vacuum pump (not shown) exhausts the plasma process chamber 101. then, the gas introducing part 105 opens a valve (not shown) and introduces the process gas at a predetermined flow rate into the plasma process chamber 101 through the mass flow controller. Then, a pressure regulating valve is adjusted to maintain the plasma process chamber 101 at a predetermined pressure. The microwave oscillator supplies the microwaves to the plasma process chamber 101 via the microwave supply unit 108 and the dielectric window 107, and generates the plasma in the plasma process chamber 101. Microwaves introduced into the microwave supply unit propagate with an in-tube wavelength longer than that in the free space, and are introduced into the plasma process chamber 101 via the dielectric window 107 through the slots, and transmit as a surface wave on the surface of the dielectric window 107. This surface wave interferes between adjacent slots, and forms a surface standing wave. The electric field of this surface standing wave generates high-density plasma. The plasma generating region P has the high electron density and allows the process gas to effectively get excited, isolated, and reacted. The electric field localizes near the dielectric window 107 and the electron temperature rapidly lowers as a distance from the plasma generation part increases, lowering damages to the device. The active species in the plasma are transported to and near the substrate 102 through diffusion, etc., and reach the surface of the substrate 102. Since the exhaust channel 106 is located closer to the plasma generating region P than the substrate 102, and the substrate 102 is arranged in an upper portion in the gas flow introduced by the gas introducing part 105 than plasma generating region P. As a result, the substrate 102's active-species concentration, e.g., oxygen radicals, can be maintained between 10⁹ and 10¹¹cm⁻³. Therefore, an extremely thin (e.g., gate oxide) film having, for example, a thickness of 2 nm or smaller can be formed on the substrate 102 through a plasma treatment with a stable controllable time, such as longer than 5 seconds.

A film formation properly selects use gas and effectively forms various deposited films, such as insulated films, e.g., Si₃N₄, SiO₂, SiOF, Ta₂O₅, TiO₂, TiN, Al₂O₃, AlN and MgF₂, semiconductor films, e.g., a-Si, poly-Si, SiC and GaAs, metal films, e.g., Al, W, Mo, Ti and Ta.

The prior art has not controlled the active-species concentration on the substrate 102 below a predetermined amount for throughput maintenance. Therefore, in an attempt to form an extremely thin film having a thickness between 0.6 nm and 2 nm on the substrate 102, the process time has been too short as 1 second or shorter for a stable film formation and surface modification. On the other hand, the instant embodiment reduces the active-species concentration, secures the controllable process time, and improves the plasma treatment quality.

The processing apparatus may use magnetic generating means for processing at lower pressure. The magnetic field used for the inventive plasma processing apparatus and method can employ a permanent magnet in addition to a coil. When the coil is used, other cooling means can be used, such as water cooling and air cooling.

A description will be given of a specific application of the microwave plasma processing apparatus 100, but the present invention is not limited to these embodiments:

First Embodiment

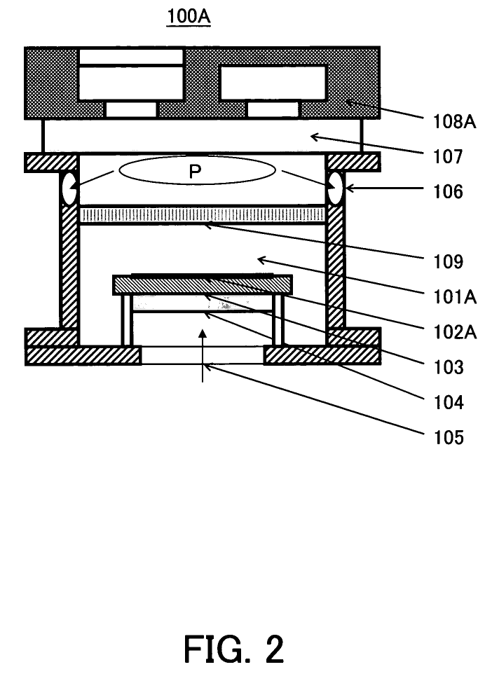

This embodiment used a microwave plasma processing apparatus 100A shown in FIG. 2 as one example of the processing apparatus 100 to form an extremely thin gate oxide film for a semiconductor device. 108A is a slot-cum non-terminal circle waveguide for introducing the microwaves into the plasma processing chamber 101A through the dielectric window 107, and 109 is a quartz conductance control plate. Elements in FIG. 2 which are the same as those in FIG. 1 are designated by the same reference numeral, and which are variations or specific examples of those in FIG. 1 are designated by the same reference numeral with a capital.

The substrate 102A used a Φ8″ P-type single crystal silicon substrate with a surface azimuth of <1 0 0> and resistivity of 10 Ωcm, from which a surface natural oxide film was removed by cleansing.

The slot-cum non-terminal circle waveguide 108A has a TE₁₀ mode, a size of an internal wall section of 27 mm×96 mm (with a guide wavelength of 158.8 mm) and a central diameter of the waveguide of 151.6 mm (one peripheral length is three times as long as the guide wavelength). The slot-cum non-terminal circle waveguide 108A is made of aluminum alloy for a reduced propagation loss. The slot-cum non-terminal circle waveguide 108A forms slots on its H surface, which introduce the microwaves into the plasma process chamber 101A. There are six radial rectangular slots at a central diameter of 151.6 mm and 60° intervals with a length of 40 mm and a width of 4 mm. The slot-cum non-terminal circle waveguide 108A is connected to a 4E tuner, a directional coupler, an isolator, and a microwave power source (not shown) having a frequency of 2.45 GHz in this order.

The processing apparatus 100A provides a conductance control plate 109 between a substrate 102A and the plasma generating region P formed near the vacuum-side surface of the dielectric window 107, which serves as an exemplary conductance adjusting means for maintaining, within a predetermined range, the active-species concentration in a process space in which the substrate 102A is located. The conductance control plate 109 is, for example, a disc or plate uniformly bored with plural Φ6 to Φ16 holes arranged at 20 mm pitches, and made of quartz. Of course, the material of the conductance adjusting means is not limited to quartz, and can use Si system insulated materials, such as quartz and silicon nitride, for problematic metallic contaminations, such as MOS-FET gate oxidation and nitridation, and aluminum, as described later, to shield the substrate from electromagnetic waves when the metallic contaminations are not in question. When the metallic contaminations and electromagnetic irradiations are problematic, metal-containing Si system insulators are applicable.

Most of the plasma excited active species, such as neutral radicals, are exhausted without reaching the substrate, and only part of the active species that flows backward through the holes in the conductance control plate 109 and diffuses contribute to processing. Changes of gas flow and exhaust conductance and control over the flow rate would result in highly precise control over the process speed and a formation of an extremely thin film of several molecules.

In operation, the substrate 102A was placed on the susceptor 103 and the exhaust system (not shown) exhausted and reduced the pressure in the plasma process chamber 101A down to 10⁻⁵ Pa. Then, the temperature control part 104 was electrified to heat the substrate 102A up to 280° C. and maintain the substrate 102A at this temperature. The gas introducing part 105 introduced nitrogen gas at a flow rate of 300 sccm into the process chamber 101A. Next, the exhaust system (not shown) adjusted a conductance valve (not shown) to maintain the process chamber 101A at 133 Pa. Next, the microwave power supply (not shown) of 2.45 GHz supplied 1.0 kW power to the slot-cum non-terminal circle waveguide 108A, and generated plasma in the process chamber 101A for 20-second processing.

In this case, oxygen gas introduced via the gas introducing part 105 is excited and dissolved into active species, such as O₂+ ions and O⁻ neutral radicals, and part of the active species flew backward through the holes in the conductance control plate 109, reached and oxidized the surface of the substrate 102A. The oxygen active-species density was 8×10⁹ cm⁻³ on the substrate during the oxidation.

After the treatment, the film quality was evaluated, such as the oxide film's thickness, uniformity, withstand pressure and leak current. The oxide film exhibited good quality, such as a thickness of 0.6 nm, uniformity of ±1.8%, withstand pressure of 9.8 MV/cm, and leak current of 2.1 μA/cm².

Second Embodiment

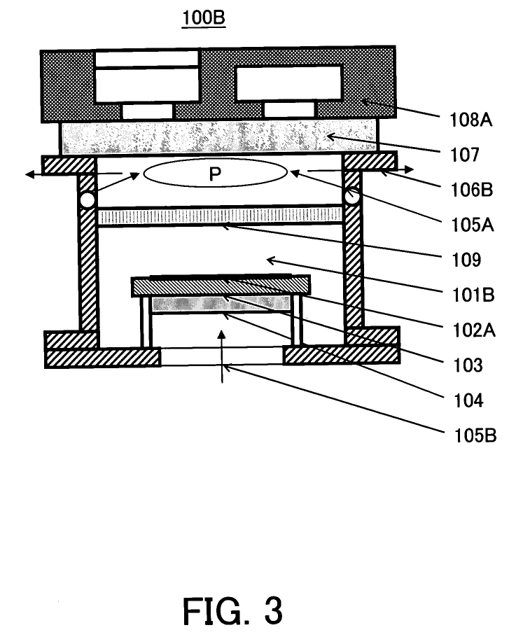

This embodiment used a microwave plasma processing apparatus 100B shown in FIG. 3 as one example of the processing apparatus 100 to form an extremely thin gate oxide film for a semiconductor device. The processing apparatus 100B has the gas introducing part that includes an inlet 105A that introduces process gas and inlet 105B that introduces inert gas, and arranges the inlet 105A and exhaust channel 106B at the side of the plasma generating region P in the plasma process chamber 101B that is divided by the conductance control plate 109, and the inlet 105B at the side of the substrate 102. Elements in FIG. 3 which are the same as those in FIG. 2 are designated by the same reference numeral, and which are variations or specific examples of those in FIG. 1 are designated by the same reference numeral with a capital.

The process gas introduced via the inlet 105A around the top of the plasma process chamber 101B is excited, ionized, reacted, and activated by the generated plasma, and contributes to low-speed high-quality treatment to the surface of the substrate 102A placed on the susceptor 103. In this case, most of the plasma excited active species, such as neutral radicals, are exhausted without reaching the substrate 102A, and only part of the active species that flows backward through the holes in the conductance control plate 109 and diffuses irrespective of the inert gas introduced by the inlet 105B contribute to processing. Changes of gas flow and ratio and exhaust conductance and control over the flow velocity would result in highly precise control over the process speed and a formation of an extremely thin film of several molecules.

The substrate 102A was placed on the susceptor 103 and the exhaust system (not shown) exhausted and reduced the pressure in the plasma process chamber 101B down to 10⁻⁵ Pa. Then, the temperature control part 104 was electrified to heat the substrate 102A up to 450° C. and maintain the substrate 102A at this temperature. The inlet 105A introduced oxygen gas at a flow rate of 10 sccm and the inlet 105B introduced Ar gas at a flow rate of 190 sccm into the process chamber 101B. Next, the exhaust system (not shown) adjusted a conductance valve (not shown) to maintain the process chamber 101B at 13.3 Pa. Next, the microwave power supply (not shown) of 2.45 GHz supplied 1.0 kW power to the slot-cum non-terminal circle waveguide 108A, and generated plasma in the process chamber 101B. The oxygen gas introduced via the inlet 105A was excited and dissolved into active species, such as O₂⁺ ions and O* neutral radicals in the plasma process chamber 101B, and part of the active species at a very small amount flew backward (i.e., towards the substrate 102A) through the holes in the conductance control plate 109 irrespective of Ar gas purge, and oxidized the surface of the substrate 102A by about 0.6 nm. The oxygen active-species density was 6×10⁹ cm⁻³ on the substrate during the oxidation.

After the treatment, the film quality was evaluated, such as the uniformity, withstand pressure, leak current, and flat band shift. The oxide film exhibited good quality, such as uniformity of ±1.8%, withstand pressure of 8.9 MV/cm, leak current of 5.0 μA/cm², and ΔVfb of 0.1V.

Third Embodiment

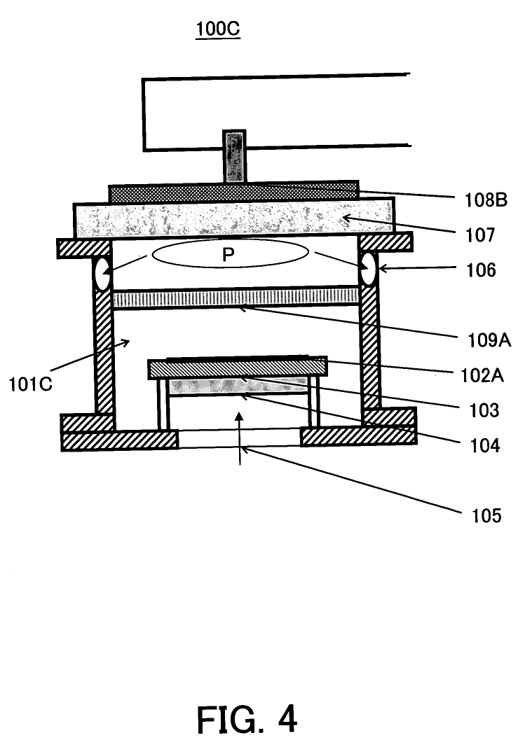

This embodiment used a microwave plasma processing apparatus 100C shown in FIG. 4 as one example of the processing apparatus 100 to form a capacitor-insulating tantalum oxide film for a semiconductor device. Here, 109A is an aluminum conductance control plate, and 108B is a coaxial multi-slot antenna. Elements in FIG. 4 which are the same as those in FIG. 2 are designated by the same reference numeral, and which are variations or specific examples of those in FIG. 1 are designated by the same reference numeral with a capital.

The conductance control plate 109A is made of aluminum and uniformly bored with plural Φ6 to Φ16 holes arranged at 20 mm pitches. The coaxial introducing slot antenna 108B has a center shaft for supply microwave power and many slots in the antenna disc. The coaxial introducing slot antenna 108B is made of an aluminum disc with a Cu center shaft for a reduced propagation loss. Each slot has a rectangular shape with a length of 12 mm and a width 1 mm, and many slots are concentrically arranged at 12 mm intervals in a tangential direction of the circle. The coaxial introducing multi-slot antenna 108B is connected to a 4E tuner, a directional coupler, an isolator, and a microwave power source (not shown) having a frequency of 2.45 GHz in this order.

The substrate 102A was placed on the susceptor 103 and the exhaust system (not shown) exhausted and reduced the pressure in the plasma process chamber 101C down to 10⁻⁵ Pa. Then, the temperature control part 104 was electrified to heat the substrate 102A up to 300° C. and maintain the substrate 102A at this temperature. The gas introducing part 105 introduced oxygen gas at a flow rate of 200 sccm and TEOT gas at the flow rate of 10 sccm into the process chamber 101C. Next, the exhaust system (not shown) adjusted a conductance valve (not shown) to maintain the process chamber 101C at 6.65 Pa. Next, the microwave power supply (not shown) of 2.45 GHz supplied 2.0 kW power to the coaxial introducing multi-slot antenna 108B, and generated plasma in the process chamber 101C. The oxygen gas introduced via the gas introducing part 105 is excited and dissolved into active species, transported toward the substrate 102A, reacted with the TEOT gas, and formed a tantalum oxide film with a thickness of 5 nm on the substrate 102A. The oxygen active-species density was 3×10¹⁰ cm⁻³ on the substrate during the film formation.

After the treatment, the film quality was evaluated, such as the uniformity, withstand pressure, leak current, and flat band shift. The oxide film exhibited good quality, such as uniformity of ±3.1%, withstand pressure of 7.3 MV/cm, leak current of 4.6 μA/cm², and ΔVfb of 0.1V.

Fourth Embodiment

This embodiment used a microwave plasma processing apparatus 100A shown in FIG. 2 as one example of the processing apparatus 100 to form an extremely thin gate nitride film for a semiconductor device. The substrate 102A was placed on the susceptor 103 and the exhaust system (not shown) exhausted and reduced the pressure in the plasma process chamber 101A down to 10⁻⁵ Pa. Then, the temperature control part 104 was electrified to heat the substrate 102A up to 380° C. and maintain the substrate 102A at this temperature. The gas introducing part 105 introduced nitrogen gas at a flow rate of 700 sccm into the process chamber 101A. Next, the exhaust system (not shown) adjusted a conductance valve (not shown) to maintain the process chamber 101A at 13.3 Pa. Next, the microwave power supply (not shown) of 2.45 GHz supplied 1.0 kW power to the slot-cum non-terminal circle waveguide 108A, and generated plasma in the process chamber 101A for 60-second processing.

In this case, the nitrogen gas introduced via the gas introducing part 105 was excited and dissolved into active species, such as N^{+, N}₂+ ions and N* neutral radicals in the plasma process chamber 101A, and part of the active species flew backward through the holes in the conductance control plate 109, reached and nitrided the surface of the substrate 102A. The nitrogen active-species density was 8×10⁹ cm⁻³ on the substrate during the nitridation.

After the treatment, the film quality was evaluated, such as the nitride film's thickness, uniformity, withstand pressure and leak current. The nitride film exhibited good quality, such as a thickness of 1.2 nm, thickness uniformity of ±1.7%, withstand pressure of 9.5 MV/cm, and leak current of 2.1 μA/cm².

Fifth Embodiment

This embodiment used a microwave plasma processing apparatus 100A shown in FIG. 2 as one example of the processing apparatus 100 to nitride a surface of an extremely thin gate oxide film for a semiconductor device. The substrate 102A was placed on the susceptor 103 and the exhaust system (not shown) exhausted and reduced the pressure in the plasma process chamber 101A down to 10⁻⁵ Pa. Then, the temperature control part 104 was electrified to heat the substrate 102A up to 350° C. and maintain the substrate 102A at this temperature. The gas introducing part 105 introduced nitrogen gas at a flow rate of 1000 sccm into the process chamber 101A. Next, the exhaust system (not shown) adjusted a conductance valve (not shown) to maintain the process chamber 101A at 26.6 Pa. Next, the microwave power supply (not shown) of 2.45 GHz supplied 1.5 kW power to the slot-cum non-terminal circle waveguide 108A, and generated plasma in the process chamber 101A for 20-second processing.

In this case, the nitrogen gas introduced via the gas introducing part 105 was excited and dissolved into active species, such as N⁺, N₂⁺ ions and N* neutral radicals in the plasma process chamber 101A, and part of the active species flew backward through the holes in the conductance control plate 109, reached and nitrided the surface of the substrate 102A. The nitrogen active-species density was 3×10¹⁰ cm⁻³ on the substrate during the nitridation.

After the treatment, the film quality was evaluated, such as the nitride film's thickness, uniformity, withstand pressure and leak current. The nitride film exhibited good quality, such as a oxide-film converted thickness of 1.0 nm, thickness uniformity of ±2.2%, withstand pressure of 10.4 MV/cm, and leak current of 1.8 μA/cm².

Further, the present invention is not limited to these preferred embodiments, but various modifications and variations may be made without departing from the spirit and scope of the present invention.

The present invention can thus provide a plasma processing apparatus and method that improves thickness controllability in forming an extremely thin film.

1. A processing apparatus that provides a plasma treatment to an object, said processing apparatus comprising:
a process chamber that accommodates an object to be processed, and generates plasma;
a gas introducing part for introducing gas into the process chamber; and
a mechanism that arranges the object at an upper side in a flow of the gas than an plasma generating region.

2. A processing apparatus according to claim 1, further comprising, between the object and the plasma generating region, a conductance adjuster for maintaining, within a predetermined range, a concentration of active species in a process space that encloses the object.

3. A processing apparatus according to claim 2, wherein said conductance adjuster is a plate bored with plural holes.

4. A processing apparatus according to claim 2, further comprising an exhaust mechanism at a side of the plasma generating region in that is partitioned by said conductance adjuster, wherein said gas introducing part is located at a side of the object in said process chamber that is partitioned by said conductance adjuster.

5. A processing apparatus according to claim 2, wherein said gas introducing part includes a first gas inlet for introducing into said process chamber process gas for the plasma treatment to the object, and a second gas inlet for introducing inert gas into said process chamber, and
wherein said processing apparatus further comprises an exhaust mechanism at a side of the plasma generating region in said process chamber that is partitioned by said conductance adjuster, and
wherein the first gas inlet is located at the side of the plasma generating region in said process chamber that is partitioned by said conductance adjuster, and the second gas inlet is located at a side of the object side in said process chamber that is partitioned divided by said conductance adjuster.

6. A processing apparatus according to claim 1, wherein the plasma treatment is oxidation or nitridation to a surface of the object.

7. A processing apparatus that provides a plasma treatment to an object, said processing apparatus comprising:
a process chamber that accommodates an object to be processed, and generates plasma;
a gas introducing part for introducing gas into the process chamber; and
an exhaust mechanism arranged closer to a plasma generating region than the object.

8. A processing apparatus according to claim 7, further comprising, between the object and the plasma generating region, a conductance adjuster for maintaining, within a predetermined range, a concentration of active species in a process space that encloses the object.

9. A processing apparatus according to claim 8, wherein said conductance adjuster is a plate bored with plural holes.

10. A processing apparatus according to claim 8, wherein said exhaust mechanism is located at a side of the plasma generating region in said process chamber that is partitioned by said conductance adjuster, wherein said gas introducing part is located at a side of the object side in said process chamber that is partitioned by said conductance adjuster.

11. A processing apparatus according to claim 8, wherein said gas introducing part includes a first gas inlet for introducing into said process chamber process gas for the plasma treatment to the object, and a second gas inlet for introducing inert gas into said process chamber, and
wherein said exhaust mechanism and the first gas inlet are located at a side of the plasma generating region in said process chamber that is partitioned by said conductance adjuster, and
wherein the second gas inlet is located at a side of the object side of said process chamber that is partitioned by said conductance adjuster.

12. A processing apparatus according to claim 7, wherein the plasma treatment is oxidation or nitridation to a surface of the object.

13. A processing apparatus that provides a plasma treatment to an object, said processing apparatus comprising:
a process chamber that accommodates an object to be processed, and generates plasma;
a gas introducing part for introducing gas into the process chamber; and
a mechanism for maintaining a concentration of active species from 10⁹ to 10¹¹ cm⁻³.

14. A processing apparatus according to claim 13, wherein said maintaining means includes, between the object and the plasma generating region, a conductance adjuster for maintaining, within a predetermined range, a concentration of active species in a process space that encloses the object.

15. A processing apparatus according to claim 14, wherein said conductance adjuster is a plate bored with plural holes.

16. A processing apparatus according to claim 14, further comprising an exhaust mechanism at a side of the plasma generating region in said process chamber that is partitioned by said conductance adjuster, wherein said gas introducing part is located at a side of the object side in said process chamber that is partitioned by said conductance adjuster.

17. A processing apparatus according to claim 14, wherein said gas introducing part includes a first gas inlet for introducing into said process chamber process gas for the plasma treatment to the object, and a second gas inlet for introducing inert gas into said process chamber, and
wherein said processing apparatus further comprises an exhaust mechanism at a side of the plasma generating region of said process chamber that is partitioned by said conductance adjuster, and
wherein the first gas inlet is located at the side of the plasma generating region in said process chamber that is partitioned by said conductance adjuster, and the second gas inlet is located at a side of the object side of said process chamber that is partitioned by said conductance adjuster.

18. A processing apparatus according to claim 13, wherein the plasma treatment is oxidation or nitridation to a surface of the object.

19. A processing method that accommodates an object in a process chamber and introduces gas containing oxygen into the process chamber to provide a plasma treatment to the object so as to form an oxide film having a thickness of 8 nm or smaller, said processing method comprising the steps of:
maintaining a concentration of active species on the object from 10⁹ to 10¹¹; and
conducting the plasma treatment for a process time longer than 5 seconds.
